(19) United States
(12) Patent Application Publication
(10) Pub. No.: US 2015/0060804 A1
(43) Pub. Date: Mar. 5, 2015

(54) ORGANIC ELECTRONIC COMPONENTS HAVING ORGANIC SUPERDONORS HAVING AT LEAST TWO COUPLED CARBENE GROUPS AND USE THEREOF AS AN N-TYPE DOPANTS

(71) Applicant: SIEMENS AKTIENGESELLSCHAFT, Munich (DE)

(72) Inventors: Andreas Kanitz, Hoechstadt (DE); Sebastien Pecqueur, La Couture (FR); Guenter Schmid, Hemhofen (DE); Jan Hauke Wemken, Nuremburg (DE)

(73) Assignee: SIEMENS AKTIENGESELLSCHAFT, Munich (DE)

(21) Appl. No.: 14/391,920

(22) PCT Filed: Apr. 8, 2013
(86) PCT No.: PCT/EP2013/057293

§ 371 Date: Oct. 10, 2014

(30) Foreign Application Priority Data
Apr. 12, 2012 (DE) 10 2012 205 945.8

(51) Int. Cl. H01L 51/00

(52) U.S. Cl. CPC H01L 51/0065; H01L 51/0067; H01L 51/5072
USPC 257/40

(57) ABSTRACT

An organic electron transport layer n-dopant. The n-dopant is used to construct organic electronic components, transistors, organic light-emitting diodes, light-emitting electrochemical cells, organic solar cells, photodiodes, and electronic components containing said n-dopant.

### CROSS REFERENCE TO RELATED APPLICATIONS

This application is based on and hereby claims priority to International Application No. PCT/EP2013/057293 filed on Apr. 8, 2013 and German Application No. 10 2012 205 945.8 filed on Apr. 12, 2012, the contents of which are hereby incorporated by reference.

### BACKGROUND

The invention relates to a novel material for n-doping of electron transport layers, to the use of these compounds for construction of organic electronic components, transistors, organic light-emitting diodes, light-emitting electrochemical cells, organic solar cells, photodiodes and electronic components comprising these compounds.

Organic electric components are formed at least partly of organic materials or compounds which, as well as the long-known insulator properties, can also have electrically conductive or semiconductive characteristics. The quality and functionality of organic electric components, for example organic solar cells, transistors, light-emitting components and photodiodes, depends essentially on the configuration of the components used. Organic electric components generally have transport layers having p-conductivity (hole conductivity) or n-conductivity (electron conductivity), the efficiency of the layers for many components being shaped to a high degree by the conductivity achievable.

The electron mobility and the number of mobile/free charge carriers generally determine the transport conductivity and hence also the injection and/or transport properties of the layers. For example, there is a rise in the efficiency of organic solar cells when a minimum amount of voltage drops away over the transport layers having p- or n-conductivity. In the case of field-effect transistors, the effective measured mobility of the semiconductor is a function of the contact resistances. If these contact resistances are minimized, it is generally possible to achieve relatively high switching frequencies in an integrated circuit. A significant influence is likewise possessed by the configuration of the transport layers in bipolar transistor components, as described in detail, for example, in DE102010041331. For organic light-emitting diodes, in contrast, the luminescence, efficiency and lifetime depend significantly on the exciton density of the light-emitting layer and is limited by this among other factors.

To increase the efficiency of the transport capacity and the injection properties, it is generally possible to take two different routes.

Firstly, by introducing a thin salt layer (thickness 0.5-3 nm) of, for example, LiF or CsF between the cathode and the electron transport layer, it is possible to achieve increased injection of electrons into the emitter layer. In the more recent literature (Huang, Jinsong et al., Adv. Funct. Mater. 2007, 00, 1-8; Wu, Chih-I et al., APPLIED PHYSICS LETTERS 88, 152104 (2006); Xiong, Tao et al., APPLIED PHYSICS LETTERS 92, 263305 (2008)), cesium carbonate is additionally also proposed as a substance for production of this intermediate layer (Briere, T. R. et al., Journal of Applied Physics, 48, 3547 (1977); Li, Yang et al., APPLIED PHYSICS LETTERS 90, 012119 (2007)). The electron transport is improved significantly as a result, but this improvement is inadequate for very high-efficiency organic light-emitting diodes.

Secondly, the doping of the matrix material can achieve an improvement in the properties of electron transport layers. However, doping in the case of the n-doping of electron transporters is much more difficult than in p-doping, since it is necessary to find doping substances having a higher HOMO (highest occupied molecular orbital) than LUMO (lowest unoccupied molecular orbital) in the electron transporter. Only in this way can an effective electron transfer from the dopant to the electron transporter take place. In general, this is achieved by materials having extremely low work functions or ionization energies (alkali metals and alkaline earth metals, and the lanthanoids).

For specific p-doping, the patent literature details organic substances which are said to improve the hole conduction of electronic components. For example, WO 2006/081780 A1 describes organic quinoid, mesomeric compounds for doping of organic semiconductive matrix material. In addition, WO 2008/138580 A1 cites specific imidazole derivatives which find use as a p-dopant for doping of an organic semiconductive matrix material. Another approach to the production of organic electronic luminescent components, in contrast, is pursued by EP 1950817 A1, which proposes specific quinoid compounds as acceptor material. What is common to all the disclosures is the use of these substances for improving the hole conduction, i.e. for p-doping of organic electric layers.

In the search for suitable substances for direct n-doping of electron transport layers, different approaches have been pursued. For example, tetrathiafulvalenes have been described as dopant substances in conjunction with strong electron acceptors from the class of the tetracyanoquinodimethanes as first charge transfer salts which have metallic conductivity (Ferraris, J. et al., J. Am. Chem. Soc. 1973, 95, 948; Coleman, L. B. et al., Solid State Commun. 1973, 12, 1125). The donor strength of the tetrathiafulvalenes, however, is insufficient for “normal” organic semiconductors, and therefore the tetrathiafulvalenes and the homologous selenium compounds thereof as dopant material seem unsuitable as dopant material. For this reason, this substance class is not preferred in the context of this discussion.

A whole series of documents from the patent literature additionally proposes dopant substances which are activated via incidence of light. For instance, DE 10 2007 014 048 A1 describes a mixture of at least one matrix material and at least one dopant material for production of a layer of a doped organic material, the dopant material being an inactive dopant precursor, and being selected from dimers, oligomers, polymers, dispiro compounds or polycycles of a dopant, in which the dopant material is broken up by supplying activation energy.

WO 2007 107306 A1 describes the use of heterocyclic radicals or diradicals, and the dimers, oligomers, polymers, dispiro compounds and polycycles thereof, as dopant for doping of an organic semiconductive matrix material, as blocker layer, as charge injection layer, as electrode material, as storage material or as semiconductor layer itself in electronic or optoelectronic components.

Further applications, for example EP 1837926 A1, EP 1837926 B1, US 2007 0252140-A1, EP 1837927 A1, WO 2007 107306 additionally disclose heterocyclic radicals or diradicals, and the dimers, oligomers, polymers, dispiro compounds and polycycles thereof, and the use thereof as organic semiconductive materials and electronic and optoelectronic components.

Further configurations of this concept and of this compound class can be found in US 2011 0108772 A1, WO 2007 107356 A1, US 2010 0233844 A1 and EP 2008 318 A1.

What is common to all these applications is that bond breaking in the dopant substance produces a radical which is then stabilized by release of an electron to the electron transport layer. The driving force is the re-aromatization of the system, by virtue of the free electron pair on the oxygen in the pyran ring or on the nitrogen in the imidazole becoming involved in the conjugation and thus forming an aromatic 6π electron system. The bond scission here forms two independent, spatially separate units which do not recombine under normal circumstances. The crucial disadvantage of this compound class presented is thus that the molecule dissociates with the bond scission and the two halves of the molecule are spatially separated irreversibly from one another. The dissociation process can limit the lifetime of the component.

U.S. Pat. No. 2,008,029 7035 A1, in contrast, describes the use of donor carbene intermediates for improvement of electron injection and electron transport in organic electronic components such as organic light-emitting diodes (OLEDs), organic field-effect transistors (OFETs) and organic photovoltaic components, especially organic solar cells. Although this application discloses donor carbene intermediates for injection purposes in electron transport layers, it is a characteristic feature of the compound classes presented that they have (several) amine substituents on the donor carbene structure, and these, after the release of an electron to the electron transport layer, stabilize the dopant as a quinoid system. This can be shown by way of example by the reaction mechanism of a compound

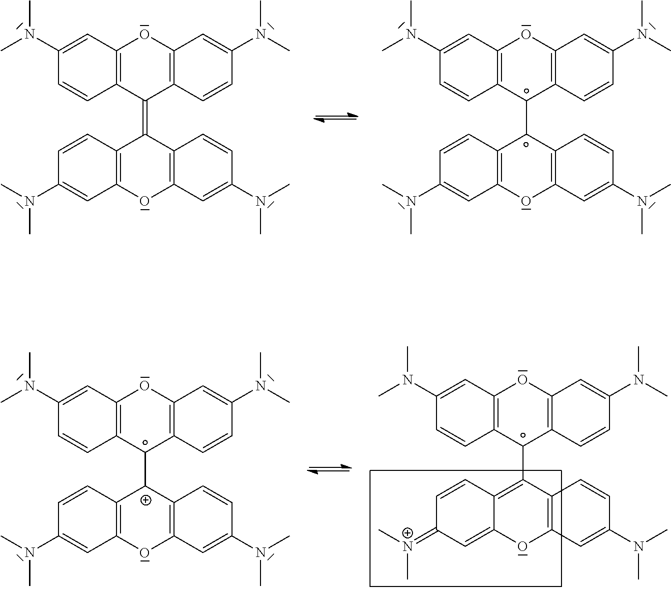

which results, after the release of an electron, in charged n-dopants having a quinoid dopant structure. It is not possible to detect aromatic stabilization of the dopants after electron release.

### SUMMARY

One potential object is to remedy the disadvantages that occur in the related art and providing an organic electronic component having an organic electron donor compound, or an electron donor compound, which finds use for doping of electron transport layers and increases the efficiency of organic electric components.

The inventors propose use of substances which, in principle, satisfy the structure shown below.

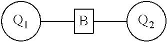

The electron donor compound if formed at least two carbene groups Q₁ and Q₂ (in general Q_{X}) coupled to one another via a bridge (B). In the simplest case, the bridge (B) is formed from at least one double bond.

A single bond is not in accordance with the proposals, since this bond dissociates in the case of electronic excitation. In addition, however, the bridge (B) may also contain quinoid ring systems with and without heteroatoms. Two quinoid ring systems are shown below by way of example, and these may also be part of more complex fused systems.

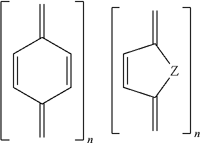

The heteroatom Z in this case is O, S, N—R, and the number n of possible quinoid units within the bridge is between n=0-20.

One example of substances according to the abovementioned schemes and of a double bond as bridge (B) can be represented as follows:

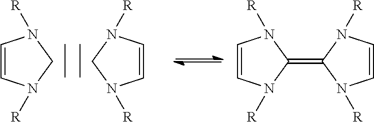

The free electron pair of the carbon is symbolized by the straight line in the reactants. The bis-carbene is formed from two individual carbene groups. The bridge (B) in the product in this case is formed of the double bond between the two carbene groups.

In the literature, the substance class having the structure shown above with a double bond in the bridge is referred to as bis-carbene compound, since it is composed in a purely formal sense of two carbenes. Since the bis-carbenes do not have carbene properties, they are referred to hereinafter, as also in the modern literature, as “super electron donors” (SED), since they are capable of acting as reducing agents. Superdonors refer to substances which, in their uncharged form, have a quinoid structure. Through electron release, the SEDs become fully or partly aromatic.

The inventors propose systems for the doping of electron transport layers, these including two quinoid units joined to one another via a double bond or analogous bridge. Such a system is in equilibrium with its diradical, without any need for the bond structure of the molecule to be broken as indicated in the related art. If a electron acceptor is present, the bis-carbene can release an electron. The result is a radical cation. The driving force for the reaction is the re-aromatization of the radical cation. Since, in a formal sense, “only” electrons are transferred and no bonds are broken, this process is reversible. This means that an equilibrium is established between donor, radical cation and (radical) acceptor anion. Since the radical anions are the least stable species in the system, the functionality in the organic component can be adjusted as follows:

a. In order to subject the acceptor to minimum stress, the donor strength of the organic electron donor compound should be adjusted such that, in the idle state of the component, only few radicals are present at the acceptor. This can prolong the lifetime of the component.

b. In the operation of the component, an electrical field is applied, which draws electrons out of the electron transporter. In this case, the organic electron donor compound is additionally activated. There is an electron transfer from the donor to the acceptor, which increases the total electron density and hence the conductivity of the transport layer.

In the SED, there is an equilibrium between the double bond structure and the diradical. For this purpose, it is not necessary for the SED first to be excited by light, as described in the related art. Electron transport materials are weak electron acceptors. A general example of an electron acceptor is, for example, BPhen (4,7-di(phenyl)-1,10-phenanthroline). The electron acceptors at least temporarily accept an electron from the bis-carbene. The driving force for the release of the electron here is the re-aromatization of the cyclic organic electron donor compound that releases electrons. The result is a radical cation. The reaction is reversible, since no bonding structures in the electron donor compound are broken. Only a partial exchange of charge takes place.

The electron transfer between two bis-carbene compounds is shown below by way of example. A bis-carbene is formed of 2 analogous 6-membered ring systems, and a further example illustrates the electron transfer in an analogous 5-membered ring system. Both bis-carbene compounds are reversibly capable of releasing an electron to an organic electron transporter (in this case, by way of example, BPhen). The respective radical anion/cation pair is formed.

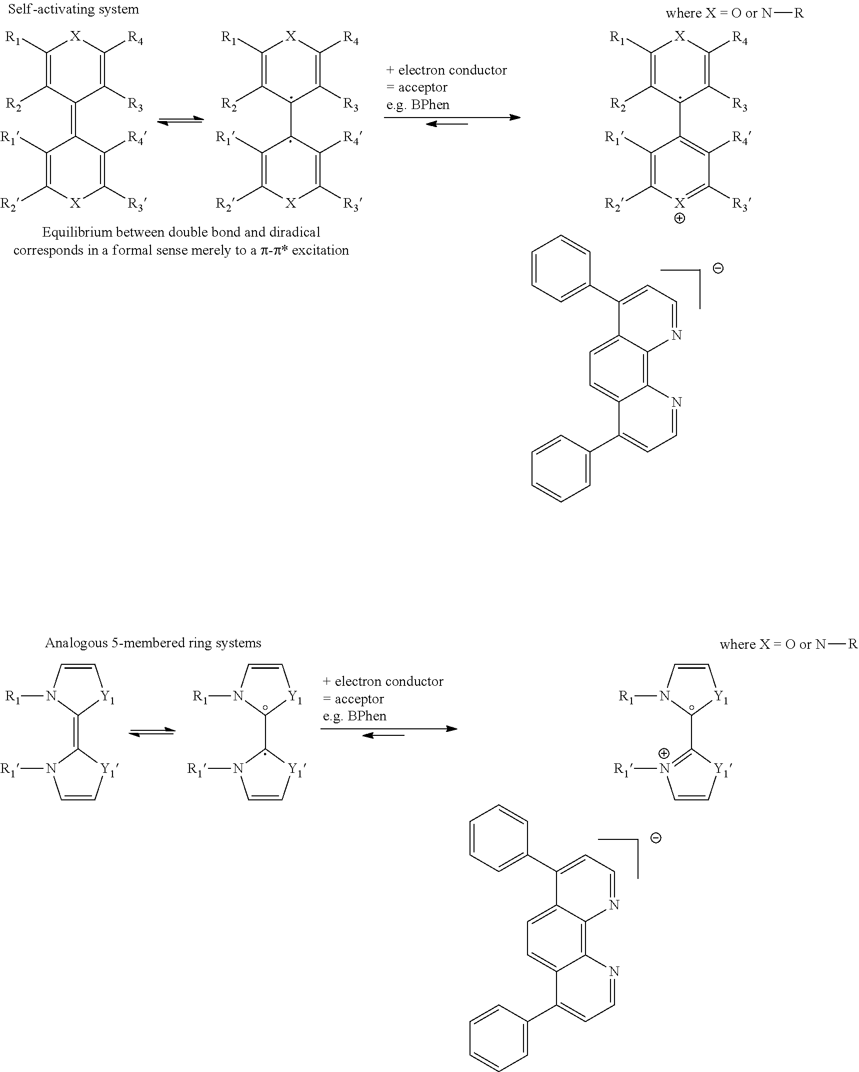

An article by Wang et al. contains a general summary of the electrochemical properties of carbene groups bridged via a double bond (“Design of new neutral organic super-electron donors: a theoretical study”, Wang, H. J. et al., J. Phys. Org. Chem. 2010, 23, 75-83).

### BRIEF DESCRIPTION OF THE DRAWINGS

These and other objects and advantages of the present invention will become more apparent and more readily appreciated from the following description of the preferred embodiments, taken in conjunction with the accompanying drawings of which:

FIG. 1 shows current-voltage characteristics of the individual compounds;

FIG. 2 shows conductivities as a function of the different GBP dopant concentrations;

FIG. 3 shows layers having different GBP dopant concentrations show that the absorption increases significantly within the visible range of 400-700 nm with rising GBP dopant concentrations;

FIG. 4 shows the results of the photoluminescence spectroscopy analysis of the quartz glass wafers produced in II.C.

FIG. 5 shows the results of reflection spectroscopy analysis of the quartz glass wafers produced in II.C.

FIG. 6 shows the cyclic voltammetry (CV) measurement of GBP dissolved in dimethylformamide and admixed with tetrabutylammonium triflate as conductive salt.

FIG. 7 shows the current-voltage characteristics of Alq3 with SED1.

FIG. 8 shows the rise in the current at low voltage values in the weak electrical field during the experiment to study the current-voltage characteristics of Alq3 with SED1.

FIG. 9 shows the current/voltage profiles of components having a pure Alq3 layer, an Alq3 layer doped with 5% SED1 and a component having an Alq3 layer doped with 5% SED1 and an additional 15 nm-thick SED1 layer which has been deposited between the calcium cathode and doped electron transport layer.

FIG. 10 shows the current/voltage characteristics of a component of size 4 mm² with an ETM-036 layer of thickness 200 nm (ETM-036 is an electron transport material from Merck OLED Materials GmbH or Merck KGaA), with and without SED1 as dopant.

FIG. 11 shows the rise in the current at low voltage values in the weak electrical field during the experiment to study the Current-voltage characteristics of ETM-036 with SED1.

FIG. 12 shows the current/voltage characteristics of a component of size 4 mm² with a TMM-004 layer of thickness 200 nm (TMM-004 is a triplet host and an electron transport material from Merck OLED Materials GmbH or Merck KGaA), with and without SED1 as dopant.

FIG. 13 shows the rise in the current at low voltage values in the weak electrical field during the experiment to study the current-voltage characteristics of TMM-004 with SED1.

FIG. 14 shows the absorption properties of an ETM-03 layer and an ETM-03 layer doped with 5/0 SED1.

### DETAILED DESCRIPTION OF THE INVENTION

Reference will now be made in detail to the preferred embodiments of the present invention, examples of which are illustrated in the accompanying drawings, wherein like reference numerals refer to like elements throughout.

The inventors propose an organic electronic component comprising at least two electrodes and an organic electron transport layer containing an organic n-dopant, which is characterized in that the n-dopant contains at least two cyclic carbene groups (Q_{X}) which are bonded via a bridge (B), said cyclic carbene groups not being dissociated on electronic excitation of the compound and at least one carbene base structure being aromatized, and the carbene groups are not joined directly to one another via a metal ligand.

The term “organic electronic component” is also understood to mean polymer-electronic components, here, for example, organic light-emitting diodes, organic solar cells, light-emitting electrochemical cells, photodiodes and organic field-effect transistors.

The organic electron donor compound is formed from or may contain at least two carbene groups bonded via a covalent bridge. The joining of two carbene groups forms what is called a bis-carbene. Carbene groups are understood to mean electrically uncharged, unstable electron deficiency compounds which have, at some point in their structure, a divalent carbon atom having an electron sextet. Carbenes thus have, in a formal sense, a free electron pair on one carbon that is not involved in a covalent bond.

If two carbene units are joined directly to one another, the result is a double bond between the two carbene groups. Preferably, the carbene groups may be cyclic hydrocarbons. Even more preferably, the carbenes are cyclic hydrocarbons which are partially unsaturated and enable resonance stabilization of the free carbene electron pair. This resonance stabilization can additionally also proceed via free, i.e. non-bonding, electron pairs of heteroatoms (e.g. oxygen, sulfur, selenium or tellurium, nitrogen, phosphorus or arsenic, etc.), which may be incorporated within the cyclic structure of the carbene groups. Preference is given to the incorporation of nitrogen as heteroatom. It is most preferable for the carbene groups to have a quinoid structure.

A molecule has a “quinoid structure” if its chemical structure contains a structural element of quinone. Quinones are benzene derivatives in which the substituents on two carbon atoms have been replaced by double-bonded oxygen, removing the aromaticity of the ring. Quinoid compounds in the context of this document also cover compounds in which one or both carbonyl groups have been replaced by ═NH, ═NOH, ═N2 or ═CH2.

The chemical bonding, i.e. coupling of the two carbene groups, can preferably lead to an organic electron donor compound which is electrically uncharged overall and preferably has a quinoid structure. Since the carbene groups within this bis-carbene structure no longer have carbene properties, this type of compounds is also referred to in the modern literature as “super electron donors” (SEDs).

The SEDs may have substituted or unsubstituted homocycles or heterocycles at every bonding-capable site of the base structure. Preferably, the substituents may be selected from substituted and unsubstituted heterocycles, for example furan, thiophene, pyrrole, oxazole, thiazole, imidazole, isoxazole, isothiazole, pyrazole, pyridine, pyrazine, pyrimidine, 1,3,6-triazine, pyrylium, alpha-pyrone, gamma-pyrone, benzofuran, benzothiophene, indole, 2H-isoindole, benzothiazole, 2-benzothiophene, 1H-benzimidazole, 1H-benzotriazole, 1,3-benzoxazole, 2-benzofuran, 7H-purine, quinoline, isoquinoline, quinazoline, quinoxaline, phthalazine, 1,2,4-benzotriazine, pyrido pyrimidine, pyrido pyrimidine, pteridine, acridine, phenazine, benzo pteridine, 9H-carbazole and bipyridine, and derivatives thereof.

Examples of possible homocycles for substitution of the bonding-capable sites of the base structure include methyl, ethyl, generally unbranched, branched, fused (decahydronaphthyl), cyclic (cyclohexyl) or fully or partly substituted alkyl radicals (C1-C20). The alkyl radicals may generally contain ether groups (ethoxy, methoxy, etc.), ester groups, amide groups, amines, carbonate groups, etc., or else halogens, especially CN and F. In the context of this document, substituted or unsubstituted aliphatic rings or ring systems such as cyclohexyl are also suitable. More particularly, these substituents may have a bridging effect. The R substituent is not limited to saturated systems, but may also include substituted or unsubstituted aromatics such as phenyl, diphenyl, naphthyl, phenanthryl or benzyl, etc.

All the R substituents of the base structure of the compound may be selected independently of one another.

The SEDs may quite generally act as reducing agents. In the case of electronic excitation, for example by light, thermal radiation or the application of a voltage, or as a result of self-activation, the compound is capable of releasing an electron to an acceptor while retaining its bonding structure. The compound may then form a resonance-stabilized cation. It can generally form salts with electron acceptors.

The electron transport layers may comprise electron transport materials, electron acceptors and organic electron donor compounds.

Electron transport materials for acceptance of electrons may preferably be selected from 2,2′,2″-(1,3,5-benzenetriyl)tris(1-phenyl-1H-benzimidazole), 2-(4-biphenylyl)-5-(4-tert-butylphenyl)-1,3,4-oxadiazole; 2,9-di-methyl-4,7-diphenyl-1,10-phenanthroline (BCP), 8-hydroxy-quinolinolatolithium; 4-(naphthalen-1-yl)-3,5-diphenyl-4H-1,2,4-triazole; 1,3-bis benzene; 4,7-diphenyl-1,10-phenanthroline (BPhen); 3-(4-biphenylyl)-4-phenyl-5-tert-butylphenyl-1,2,4-triazole; bis(2-methyl-8-quinolinolate)-4-(phenylphenolato)aluminum; 6,6′-bis-2,2′-bipyridyl; 2-phenyl-9,10-di(naphthalen-2-yl)anthracene; 2,7-bis-9,9-dimethylfluorene; 1,3-bis benzene; 2-(naphthalen-2-yl)-4,7-diphenyl-1,10-phenanthroline; 2,9-bis-(naphthalen-2-yl)-4,7-diphenyl-1,10-phenanthroline; tris(2,4,6-trimethyl-3-(pyridin-3-yl)phenyl)borane; 1-methyl-2-(4-(naphthalen-2-yl)phenyl)-1H-imidazo phenanthroline; phenyldipyrenylphosphine oxide; naphthalenetetracarboxylic dianhydride or imides thereof; perylenetetracarboxylic dianhydride or imides thereof; materials based on siloles having a silacyclopentadiene unit or further heterocycles as described in EP 2 092 041 B1.

Electron acceptors may be 2,3,5,6-tetrafluoro-7,7,8,8-tetracyanoquinodimethane, pyrazino phenanthroline-2,3-dicarbonitrile and dipyrazino quinoxaline-2,3,6,7,10,11-hexacarbo-nitrile.

For doping purposes, the organic electron donor compounds may be applied to a layer together with an electron acceptor or the electron transport materials. In this case, the compounds can be processed either in the gas phase or in the liquid phase. In the case of gas phase deposition, both dopant and matrix material are vaporized under high vacuum together, preferably from different sources, and deposited as a layer. In the case of processing from the liquid phase, the organic electron donor and the matrix material are dissolved in a solvent and deposited by printing techniques, spin-coating, knife-coating, slot-coating, etc. The finished layer is obtained by vaporizing the solvent. It is possible to establish any desired doping ratios via the different mass ratios of organic electron donor compound to the electron acceptor.

The two carbenes are not joined or bridged directly to one another via a metal ligand. However, this does not mean that one or both carbene groups cannot have a metal ligand within the bonding structure thereof. As metal-containing substituents, the organic electron donor compounds may contain, by way of example, but without limitation, ferrocenyl, cyclopentadienyldicarbonyliron or phthalocyanines and porphyrins.

In a particular embodiment, the organic electronic component is characterized in that the carbene groups of the organic n-dopant are bonded directly to one another by a double bond. It is a particular feature that, in the case of electronic excitation, the bonding structure of the organic electron donor compound is not broken. This means that the two carbenes in the electronically excited state are still bonded to one another via a single bond and the molecule does not dissociate. For n-doping of electrical transport layers, compounds of the following type are regarded as being particularly good:

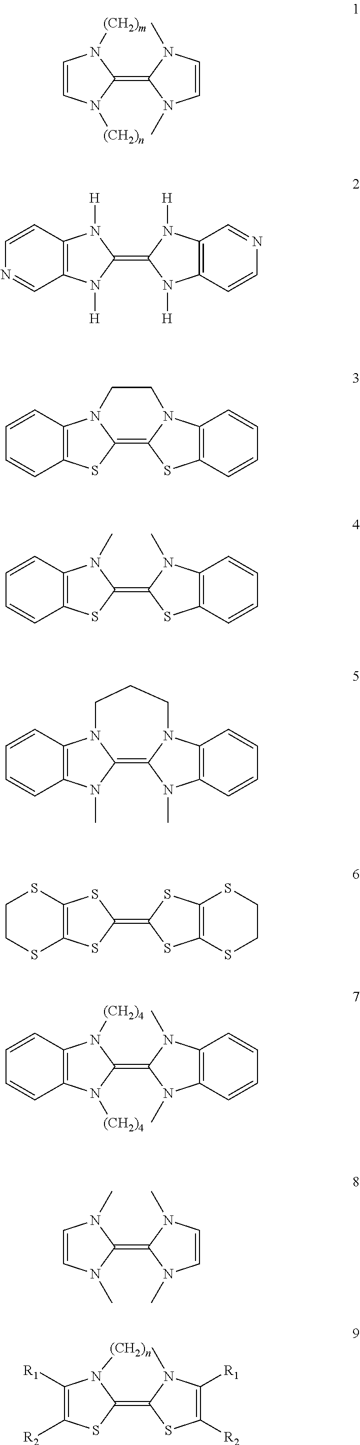

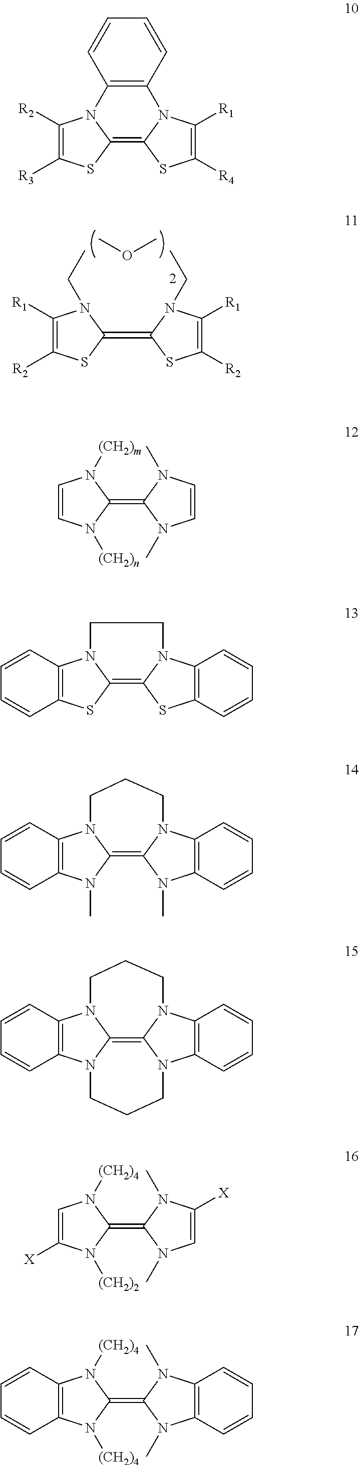

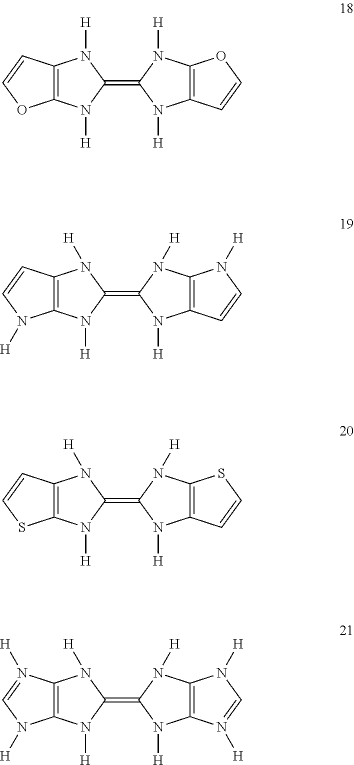

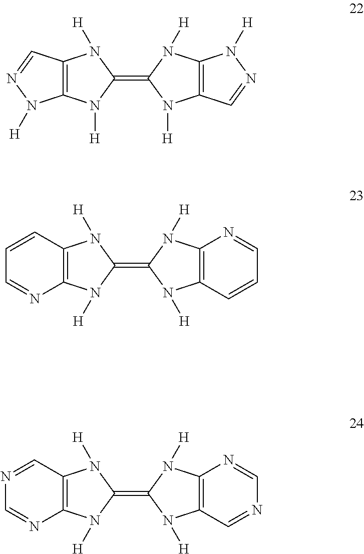 [SMILES: c1n[nH]c2c1N/C(=C1/Nc3cn[nH]c3N1)N2 ; c1cnc2c(c1)N/C(=C1/Nc3cccnc3N1)N2 ; c1ncc2c(n1)N/C(=C1\Nc3cncnc3N1)N2]

The compounds represented above show, by way of example and in a non-limiting manner, base compounds of organic electron donor compound having a double bond as bridge (B). The variables shown in these compounds mean m=2-4, n=2-4; R₁, R₂, R₃, R₄=hydrogen or methyl or COMe or CO₂Et. Instead of the hydrogen atoms, it is possible for any desired organic or organometallic substituents to be present. Particular preference is given in the context of this document to those variants which, rather than the hydrogens (H), have radicals (R) as listed above for substitution of the base structure of the SEDs. Particular preference is additionally given to the compounds having nitrogen as heteroatom in the base structure of the compound.

In a particular embodiment, the organic electronic component is characterized in that the bridge (B) of the n-dopant contains at least one quinoid ring system. The quinoid ring systems may either be based purely on carbon or contain heteroatoms. In addition, the bridging quinoid units may be part of complex fused systems. The number of quinoid units present in the bridge may be between 0 and 20 units. If no quinoid unit is present between the carbene groups, the two carbenes are necessarily joined directly to one another via a double bond.

A further, particular embodiment includes the organic electronic component, characterized in that at least one of the carbene groups of the organic n-dopant contains a 5- or 6-membered ring having at least 1 heteroatom. As well as the bis-carbene compounds shown above, the drawing below shows a cyclic carbene compound which is formed of a 5-membered ring, and further compounds containing a cyclic 5-membered ring. The structure having the letter (A) denotes a fused aromatic system (compound 27+28+29).

In a further embodiment of the organic electronic component, the 5-membered ring of the organic n-dopant may be joined to the second carbene group by an additional bridge (dotted line in compounds 28+29). In addition, in a particular embodiment, the carbene group may be joined to the other carbene group via two additional bonds in the ring system (compound 29).

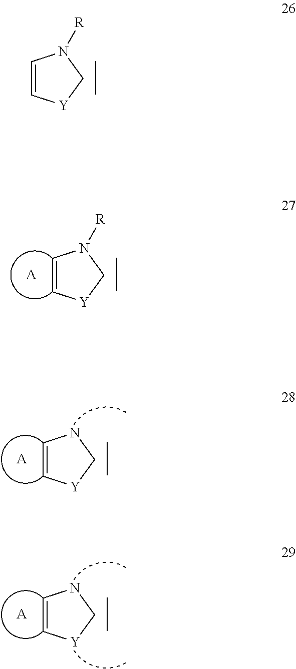

In the above example, Y denotes 0, S or N—R, particular preference being given to the N—R derivatives.

The R substituents mentioned in the above example may be selected in an equivalent manner to the substituents already detailed for the bonding-capable sites in the base structure.

In a particular embodiment of the organic electronic component, the organic n-dopant is characterized in that the carbene groups are formed of identical 5-membered rings having at least 1 heteroatom in the base structure thereof. However, this substance class excludes the tetrathiafulvalenes and derivatives thereof.

In further particular embodiments of the organic electronic component, the organic n-dopant is characterized in that at least one of the carbene groups contains a 6-membered ring. Examples of these particular embodiments are shown in the following drawing:

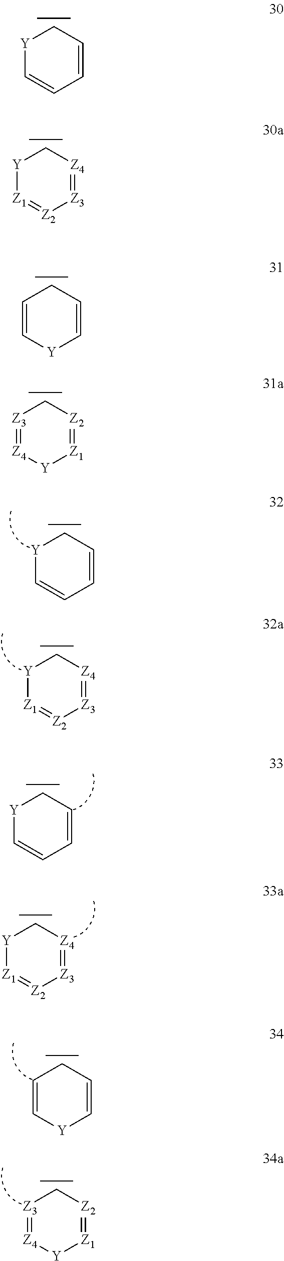

The first two structural formulae (compounds 30+30a) exhibit a cyclic carbene group which derives from a heteroaromatic. The heteroatom Y is at a position not conjugated to a double bond. The with Z positions (Z₁ to Z₄) identify atoms which are bonded by a double bond and may take the form of C—H, C—D, C—R (the definition is equivalent to the definition of R for substituted 5-membered rings) or N. For the Zᵢ positions, it is possible that the adjacent Z (Zᵢ and Zᵢ₊₁) may be joined together to form more highly fused systems (naphthalene, anthracene, etc., or the hetero analogs thereof).

The dotted arcs indicate those positions at which bridging to other carbene groups is possible. For the bridging to other carbene groups, it is possible in principle to distinguish between three options. In the first option, the bridge is on the nonaromatic atom or, secondly, on one of the C—R formed from Z or, thirdly, of a combination of the different Z positions (i. and i., ii. and ii., i. and ii.).

In a further preferred embodiment, the two carbene groups may have the same structure and each contain at least one 5- or 6-membered ring. According to the configuration of the bridge unit, the bis-carbene in this particular case would then have mirror symmetry.

In a particular embodiment of the organic electronic component, the organic n-dopant is characterized in that at least one of the carbene groups contains a tetraazinodihetarene. The tetraazinodihetarenes were synthesized in 1986 by Eichenberger and Balli (Eichenberger, T. and Balli, H., Helv. Chim. Acta 1986, 69, 1521-1530). This substance class includes, in a formal sense, an s-tetrazine in the oxidation state of a 1,4-dihydro-1,2,4,5-tetrazine and fused-on heterocyclic ring systems, for example pyridine, quinoline and isoquinoline. The planar nitrogen atoms that the bridgehead of the tetrazine ring each contribute two electrons to the ₙ system and thus lead to over-compensation for the acceptor character of the pyridine-type nitrogen atoms. This substance class can also be classified as a “Weitz-type” donor.

In a further embodiment of the organic electronic component, the organic n-dopant may be characterized in that it contains a bis-pyran or is formed by a bis-pyran. The synthesis of the bis-pyrans was devised by A. Kanitz among others. As an example of the synthesis of the bis-pyrans, the disclosure content of the patent application WO2007/028738 is added here.

In yet a further embodiment of the organic electronic component, the organic n-dopant is characterized in that it comprises a 2,2′,6,6′-tetraphenyl-4,4′-dipyran or consists of a 2,2′,6,6′-tetraphenyl-4,4′-dipyran.

A further preferred embodiment of the organic electronic component is characterized in that the carbene groups of the organic n-dopant are additionally joined to one another via at least one second bridge. Some non-limiting examples of multiply bridged super-donors are given above (for example the compounds 1, 3, 5, 6, 7, 9, 15). In addition, additional bridging options in principle in the case of 5- or 6-atomic cyclic compounds are given above (for example compounds 28, 29 or compounds 32, 33).

In addition, organic electron transport layers containing an organic n-dopant are characterized in that the n-dopant contains at least two cyclic carbene groups (QX) which are bonded via a bridge (B), said cyclic carbene groups not being dissociated on electronic excitation of the compound and at least one carbene base structure being aromatized, and the carbene groups are not joined directly to one another via a metal ligand. More particularly, it is disclosed explicitly that individual properties and configurations of the n-dopants of the electron transport layers, or combinations of said properties and configurations, correspond to those which have been described above in the context of the description of the n-dopants of the organic electronic components.

Also included in the proposal is an organic electron transport layer n-dopant, characterized in that the n-dopant contains at least two cyclic carbene groups (QX) which are bonded via a bridge (B), said cyclic carbene groups not dissociating on electronic excitation of the compound and at least one carbene base structure being aromatized, and the carbene groups are not joined directly to one another via a metal ligand. More particularly, it is disclosed explicitly that individual properties and configurations of the organic electron transport layer n-dopants, or combinations of said properties and configurations, correspond to those which have been described above in the context of the description of the n-dopants of the organic electronic components.

In addition, the organic electronic components can be used for production of polymer-electronic components. These include all the processing methodologies for production of organic light-emitting diodes, organic solar cells, light-emitting electrochemical cells, photodiodes and organic field effect transistors.

### Examples

### I. Synthesis

### I.A) Two-stage synthesis of 2,2′,6,6′-tetraphenyl-4,4′-dipyran (GBP)

GBP is synthesized in two stages.

### I.A-1) Synthesis of diphenylpyrrylium perchlorate

30 g of acetophenone (0.25 mol) are dissolved in 250 g of ethyl orthoacetate (1.68 mol) and brought to boiling. Then 18 g of 70% perchloric acid (0.13 mol) are slowly added dropwise to the solution. The temperature is reduced to 80° C. and the reaction is continued overnight. After cooling, the precipitate formed is filtered off with suction and washed with ether. This gives diphenylpyrrylium perchlorate having a melting point of 222° C. according to the following reaction scheme as reaction product.

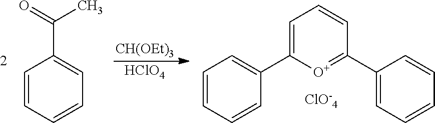

### I.A-2) Synthesis of 2,2′,6,6′-tetraphenyl-4,4′-dipyran

0.2 mol of diphenylpyrrylium perchlorate is heated under reflux in pyridine and 0.01 mol of triphenylphosphine for 3 h. After cooling, the precipitate formed is filtered off with suction and washed with ether. This gives 2,2′,6,6′-tetraphenyl-4,4′-dipyran (GBP, gamma-bipyran) according to the following reaction scheme as reaction product:

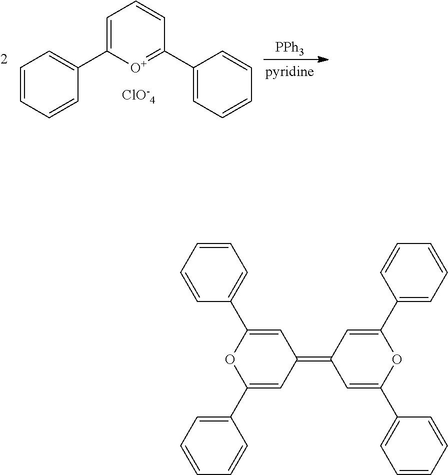

### I.B) Two-stage synthesis of N,N,N′,N′-tetramethyl-7,8-dihydro-6H-dipyrido diazepine-2,12-diamine (SED1)

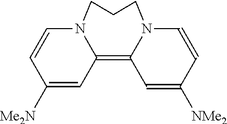 [SMILES: CN(C)C1=CC2=C3C=C(N(C)C)C=CN3CCCN2C=C1]

SED1 is synthesized in two stages by a modified method according to J. A. Murphy, J. Garnier, S. R. Park, F. Schoenebeck, S. Zhou, A. T. Turner, Org. Lett. 2008, 10, 1227.

### I.B-1) Synthesis of 1,3-bis(N,N-dimethyl-4-aminopyridinium)-propane diiodide

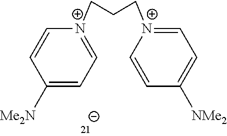 [SMILES: CN(C)c1cc[n+](CCC[n+]2ccc(N(C)C)cc2)cc1]

A solution of 4.58 g (37.5 mmol) of 4-dimethylaminopyridine and 4.44 g (15 mmol) of 1,3-diiodopropane are stirred under reflux in 100 ml of acetonitrile in an inert gas atmosphere overnight. After cooling, the solid residue is filtered off.

20 ml of diethyl ether are added to the acetonitrile solution, and more solid matter precipitates out. The solid residue is washed three times with 30 ml of diethyl ether and dried under reduced pressure. This gives 1,3-bis(N,N-dimethyl-4-amino-pyridinium)propane diiodide as a white powder, m.p. 280-285° C. (dec.); λₘₐₓ (KBr)/cm⁻¹ 3005, 1651, 1574, 1540, 1404, 1204, 1185, 1129, 1067, 1036, 829, 805; ¹H NMR (400 MHz, DMSO-d6): 2.36 (2H, quintet, J=7.2 Hz, CH₂), 3.20 (12H, s, CH₃), 4.27 (4H, t, J=7.2 Hz, NCH₂), 7.05 (4H, d, J=7.7 Hz, ArH), 8.30 (4H, d, J=7.7 Hz, ArH); ¹³C NMR (100 MHz, DMSO-d6): 31.0 (CH₂), 39.8 (4 CH₃), 53.6 (2 CH₂), 107.8 (2CH), 141.8 (2CH), 155.8 (2C); m/z (ESI⁺) 413, 143 (100), 96 (10).

### I.B-1) Synthesis of N,N,N′,N′-tetramethyl-7,8-dihydro-6H-dipyrido diazepine-2,12-diamine (SED1)

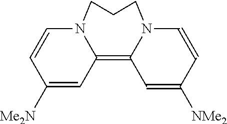 [SMILES: CN(C)C1=CC2=C3C=C(N(C)C)C=CN3CCCN2C=C1]

A mixture of 5.4 g (10 mmol) of 1,3-bis(N,N-dimethyl-4-amino-pyridinium)propane diiodide and 1.45 g (60 mmol) of NaH (obtained in powder form from a 60% dispersion in mineral oil by washing with cyclohexane and subsequent drying under reduced pressure) is introduced under a protective argon gas atmosphere into a 100 ml three-neck flask equipped with an ammonia supply and a dry ice condenser. The flask is cooled to −80° C. and the dry ice condenser is filled with liquid nitrogen. While stirring, 70 ml of ammonia are condensed into the flask. A yellow solution forms, which is stirred under reflux at −30° C. for a further 90 minutes. In the course of this, the color of the solution changes from yellow to red. The solution is allowed to warm up to room temperature and the excess ammonia is evaporated off. The deep red solid is extracted with dry ether, concentrated and dried under reduced pressure. The black product is sublimed under reduced pressure at 105-110° C. Because of the fact that the material melts before subliming, only 220 mg of sublimed material are obtained. An improvement in yield can be achieved by scratching the residual material from the vacuum still and subjecting it to a further sublimation.

### I.C) Production of Organic Electrically Conductive Layers

### I.C-1) Production of Organic Electrically Conductive Layers Comprising GBP

By thermal evaporation, a 200 nm-thick layer of the electron conductor BCP (2,9-dimethyl-4,7-diphenyl-1,10-phenanthroline) is deposited on an ITO (indium tin oxide=indium-doped tin oxide) electrode. The counterelectrode used is a 150 nm-thick aluminum layer.

In four further experiments, the GBP prepared in I.A) is incorporated by doping in concentrations of 2%, 5%, 15% and 25% relative to the evaporation rate of the BCP.

### I.C-2) Production of Organic Electrically Conductive Layers Comprising SED1

Prefabricated ITO glass substrates are treated by an oxygen plasma for 10 minutes and transferred as quickly as possible to an evaporator within an argon-filled glovebox having a water content less than 2 ppm.

The thermal evaporation is effected at a base pressure of less than 2×10⁻⁶ mbar, which is maintained over the course of the entire vapor deposition process.

The electron conductor and the dopant are heated simultaneously to a temperature just below the evaporation point thereof. Subsequently, the dopant is heated further until a constant evaporation rate has been achieved. The same procedure is followed with the electron conductor and, with evaporation rates constant on each side, the slide valve of the evaporator is opened.

The rate of electron transport is set to 1 Å/s, and the dopant rate is chosen as a function of the evaporation rate of the electron transport material and the desired dopant concentration.

Before the application of the counterelectrode, on completion of vapor deposition, both sources are cooled down to below 40° C.

The counterelectrode is deposited by thermal vapor deposition and includes a stack of a 10 nm-thick calcium layer and a 150 nm-thick aluminum layer.

The deposition is started at a deposition rate of 0.5 Å/s by opening the slide valve, and then the deposition rate is increased gradually to 5 Å/s.

The electrodes thus produced are subjected to a physical characterization.

### II) Physical Characterization of the GBP Dopants

### II.A Current-Voltage Characteristics

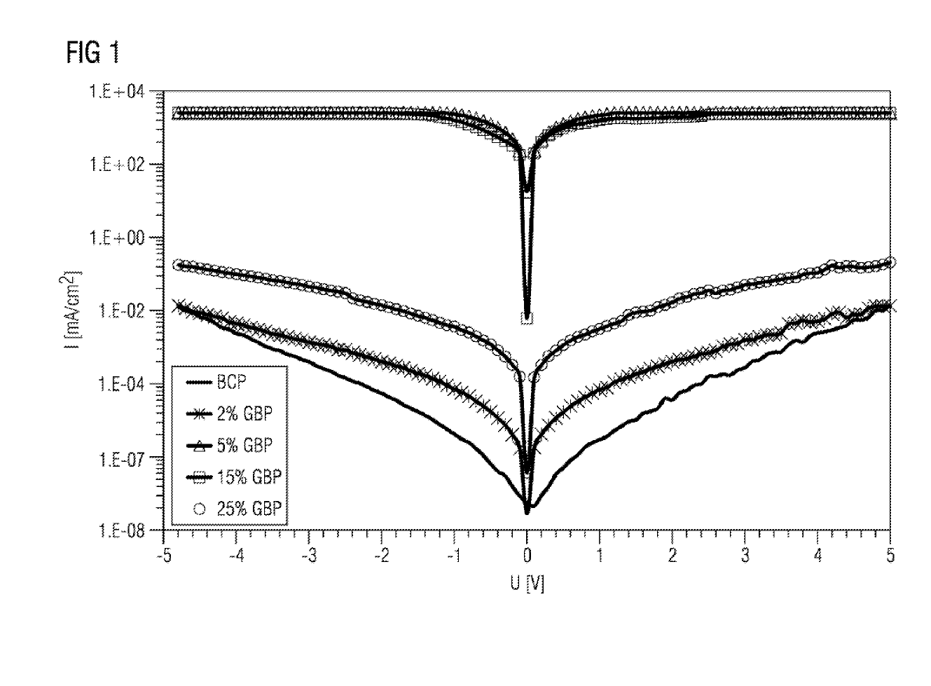

Current-voltage characteristics were recorded on components of size 4 mm² of the electrodes produced in I.C-1. The characteristics of the individual compounds are shown in FIG. 1. The proportion of GBP was 2%, 5%, 15% and 25% relative to the evaporation rate of the BCP.

For all the GBP dopant concentrations, it is possible to show that the doping has a concentration-dependent effect on the IV characteristic. At a GBP dopant concentration of 2%, only a slight increase in the current density is found, whereas GBP dopant concentrations of 5% and 10% have a distinct rise in the current densities compared to the reference component. A GBP dopant concentration of 25%, in turn, is too high to lead to an effective current density; in this case, the current density is below the current densities of the electrodes having GBP dopant concentrations of 5% and 10%.

Sufficiently strong doping effects are achieved in this case, by way of example, with GBP dopant concentrations in the range between 5% and 15%.

The horizontal regions of the characteristics do not constitute a current limitation for the component, but are caused by the safety-related current limits for the component. It is generally the case that the smaller the voltage at which the component attains the maximum current density, the better the doping effect.

The symmetric behavior of the current-voltage characteristic shows, for the undoped BCP layer and the layers having the different GBP dopant concentrations, that the electron injection is independent of the work function of the metal electrodes and works equally well for aluminum and ITO electrodes. This is a desirable property for good dopants.

### II.B Conductivity Measurements

Conductivity substrates were coated using the GBP dopant concentrations of 2%, 5%, 15% and 25% selected in I.C-1, based on GOP. For this substrate type, it is unnecessary to apply a counterelectrode of aluminum. In addition, in order to rule out conductivity being a function of component area and thickness, a total of 9 components of different dimensions were produced.

For the components thus produced, a layer conductivity having the following specific values for the different dopant concentrations was determined:

TABLE 1
Electrical conductivities for different GBP dopant concentrations

| GBP dopant content in BCP in % | Electrical conductivity in S/m |
|---|---|
| 2% | 4.23E−10 |
| 5% | 4.99E−10 |
| 15% | 7.42E−10 |
| 25% | 1.30E−08 |

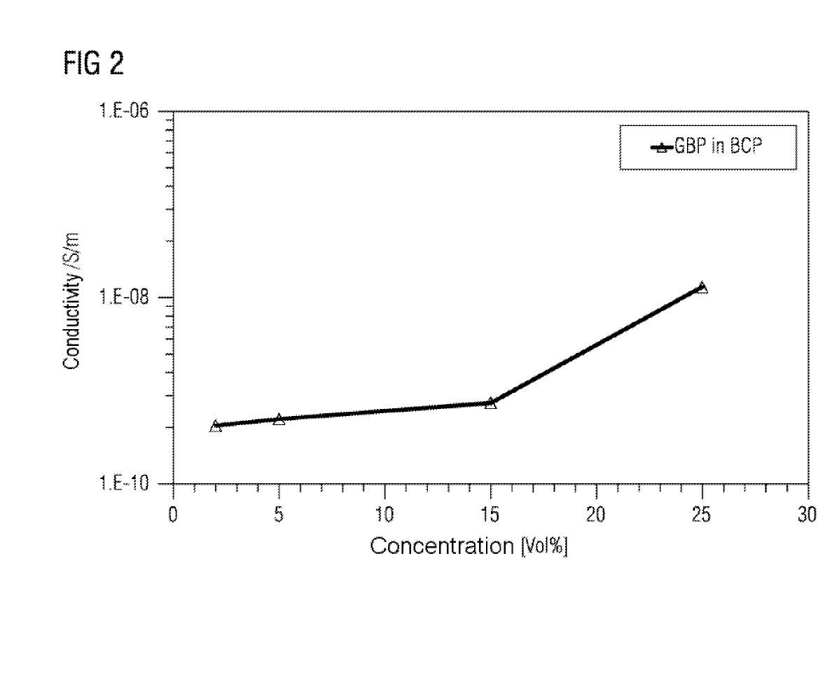

The conductivities as a function of the different GBP dopant concentrations are illustrated once again in FIG. 2. The plot found does not correspond to the results of the IV characteristics. The conductivity is small for the conductivity substrate with an undoped GCP layer and rises with increasing GBP dopant concentration. The conductivities measured, even at the highest measured GBP dopant concentrations, are not in the orders of magnitude that would be expected from a good dopant (1E-5 to 1E-3 S/m).

Together with the IV characteristics from II.A, it can be concluded that the GBP-doped layers do have good charge carrier injection and current carrying capacity, but the conductivity is improved only slightly at very low fields. The dopants used are thus a substance class which can improve charge carrier injection.

Without being bound by the conductivity values presented, it cannot be ruled out that layers having even higher conductivity can be produced with higher GBP dopant concentrations.

### II.C Absorption Spectra

To determine the emission and reflection spectra of different doping compositions, layers having different GBP dopant concentrations analogously to I.C-1 were deposited onto quartz glass wafers. These samples are executed without electrical contacts and serve merely to measure the optical layer properties.

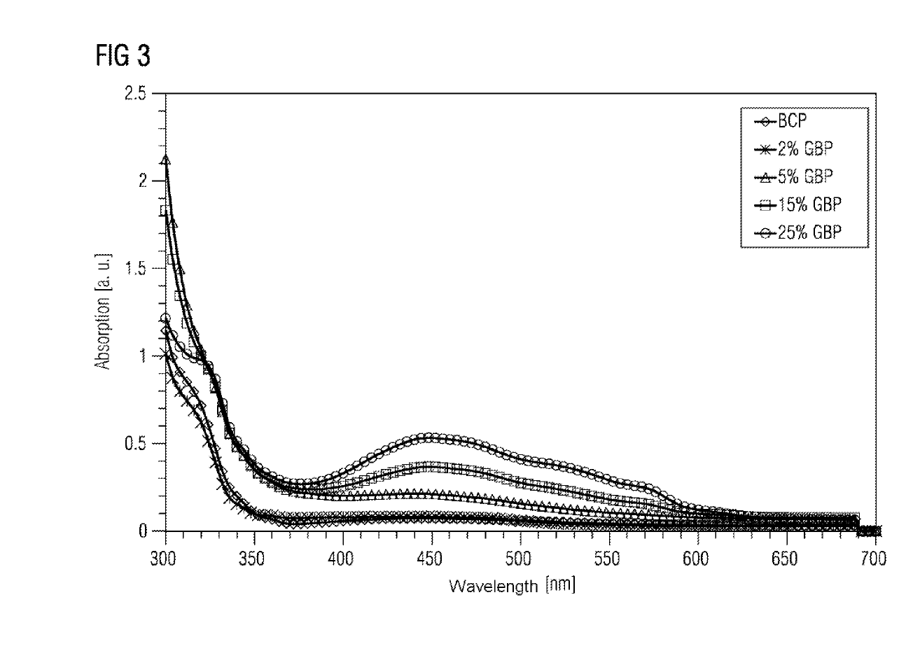

The absorption spectra (see FIG. 3) of the layers having different GBP dopant concentrations show that the absorption increases significantly within the visible range of 400-700 nm with rising GBP dopant concentrations. This increase becomes particularly clear in the blue/green region of 400-550 nm, the effect of which is that the layer has a distinct red appearance to the human eye. Without being bound by theory, the increase in the absorption with rising GBP dopant concentration is firstly possibly because of the formation of charge transfer complexes and secondly because of the reddish base color of the GBP.

### II.D Photoluminescence Spectra (PL Spectra)

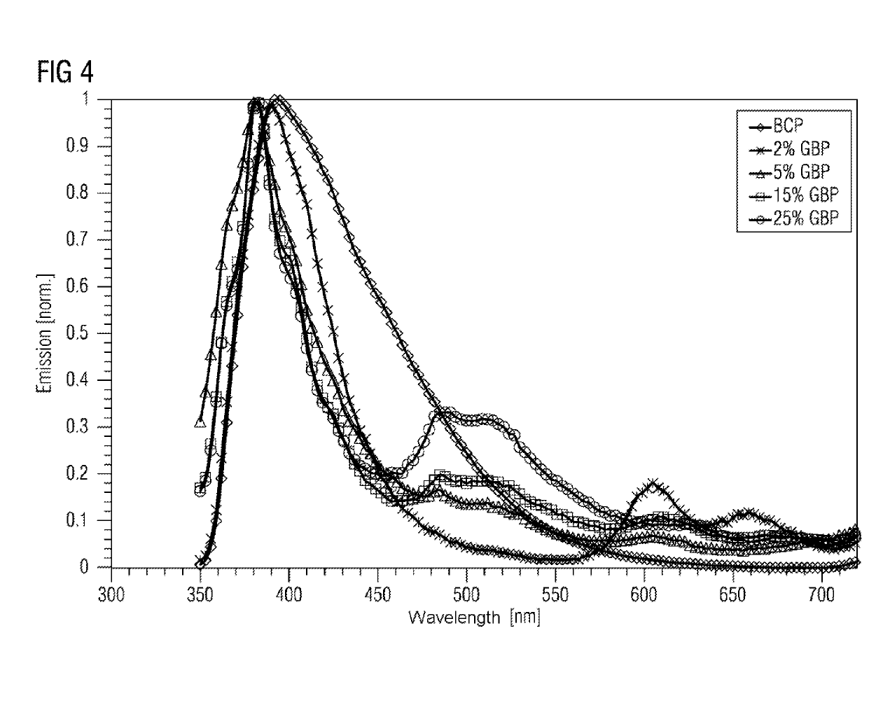

The quartz glass wafers produced in II.C were analyzed by photoluminescence spectroscopy. The results are shown in FIG. 4. The comparison of the PL spectra of pure BCP layers with GBP-doped BCP layers shows that the emission maximum shifts from 396 nm to 383 nm. In addition, a distinct second peak forms at 480-540 nm for the GBP-doped layers, which becomes increasingly pronounced with rising GBP dopant concentration. Without being bound by theory, the shift in the emission maximum is attributed to the formation of charge transfer complexes, while the second peak is attributable to the GBP. The high emission can especially have a positive effect for organic photodetectors and solar cells.

### II.E Reflection Spectra

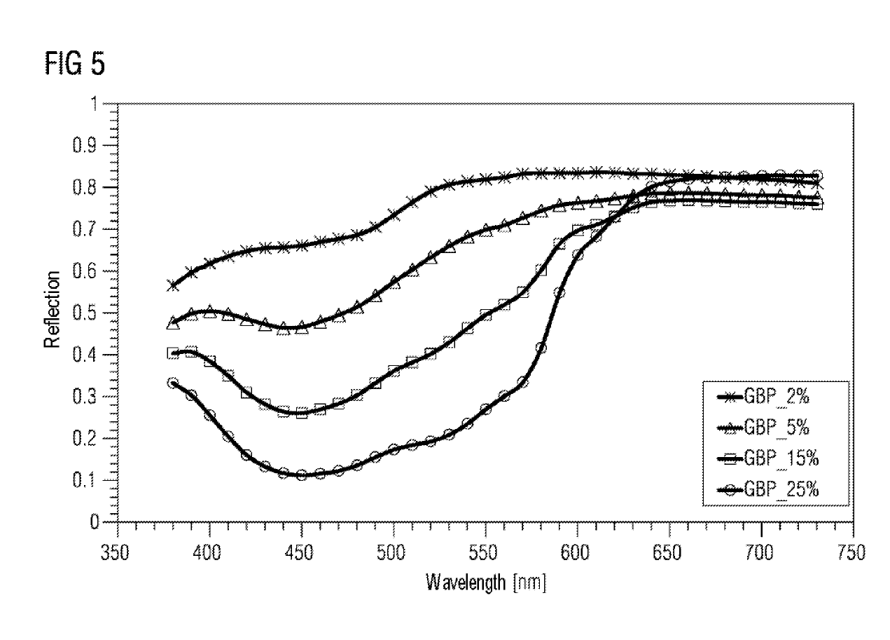

The quartz glass wafers produced in II.C were analyzed by reflection spectroscopy. The results of the reflection spectra are shown in FIG. 5. The comparison of the reflection spectra of pure BCP layers with GBP-doped BCP layers shows a GBP concentration-dependent decrease in the reflection in the blue/green wavelength range (420-550 nm), whereas the reflection in the red region is GBP concentration-independent. In purely optical terms, this is also found in the layers, the hue of which becomes ever darker and redder to the human eye with rising GBP concentration.

### II.F Cyclic Voltammetry (CV) Measurement

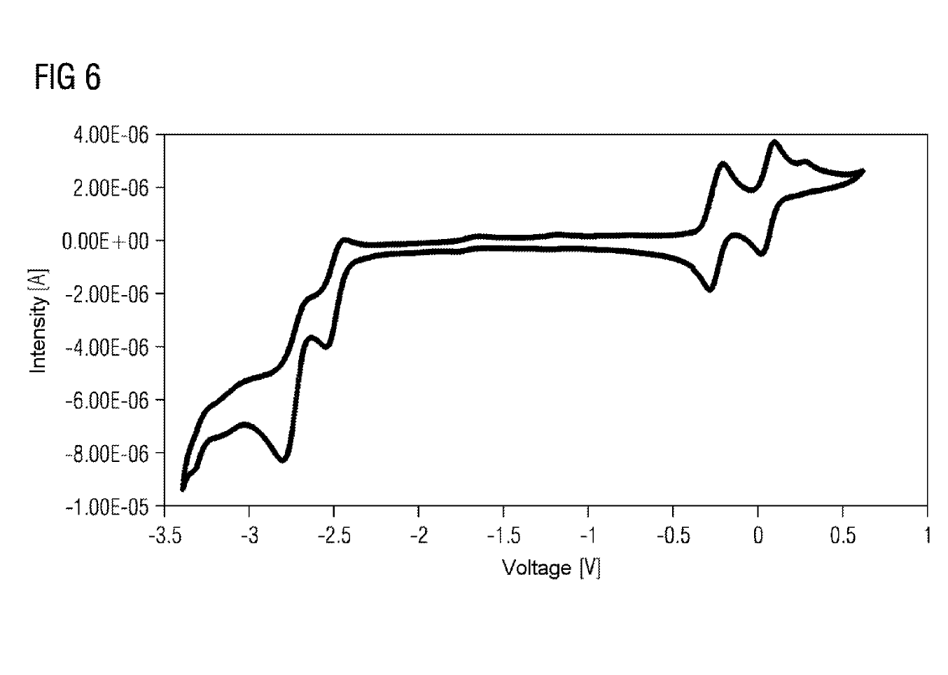

0.8±0.1 mg of GBP were dissolved in 986.7±0.1 mg of dimethylformamide and admixed with 67.2±0.1 mg of tetrabutylammonium triflate as conductive salt. All the components were fully dissolved. Three platinum wires served as working electrode, counterelectrode and reference electrode. A current-voltage characteristic was recorded between −3 V and 1 V, based on the reference electrode. Ferrocene served as reference for calibration of the voltage axis. The onset of the first one-electron oxidation was to 0.05 V against a standard hydrogen electrode (—4.45 eV vs. vacuum level). The onset of the corresponding reduction was found to be +0.22 V against a standard hydrogen electrode (−4.62 eV vs. vacuum level). Both of these results are shown FIG. 6. The average value gives a HOMO level of −4.53 eV.

This shows, by way of example, the potential of this compound class. Even though the HOMO is relatively low, an improvement in the conductivity, especially in the injection, can nevertheless be observed.

### III) Physical Characterization of the SED1 Dopants

III.A Current-Voltage Characteristics with SED1 as Dopants

Measurement results for the SED1 dopant with different electron transport materials and different layer structures are presented. The measurement data are obtained on components which were produced according to I.C-2.

III.A-1 Current-Voltage Characteristics of Alq3 with SED1

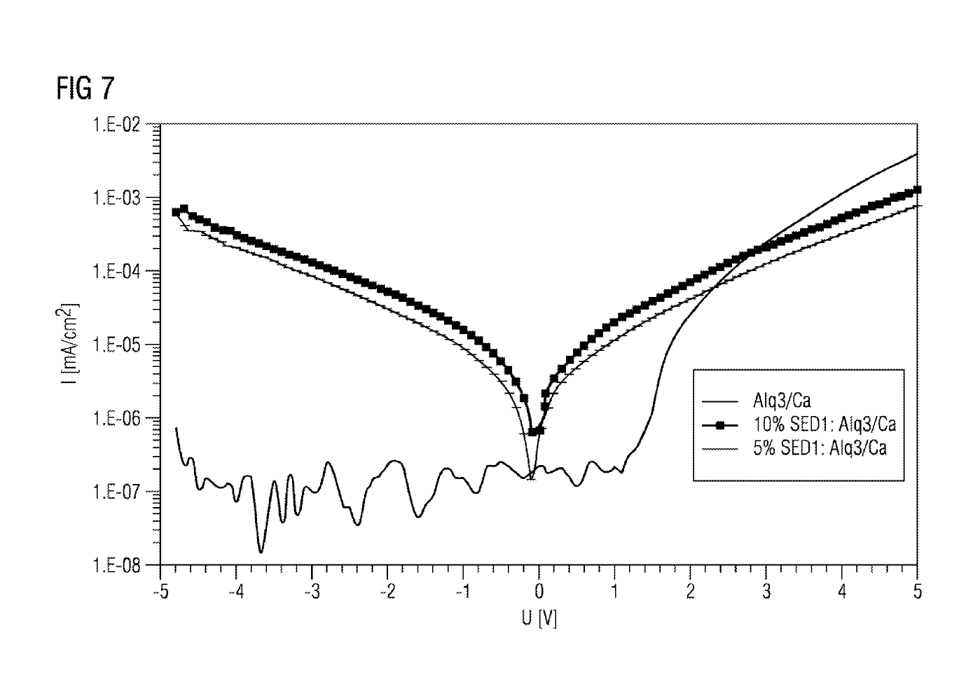

3 samples of a component of size 4 mm² are produced with Alq3, an electron transport material from Sensient Imaging Technology GmbH. For the blank sample, a 200 nm-thick Alq3 layer, as already described above, is deposited by vapor phase deposition on an ITO electrode. In addition, two further samples with 5% and 10% SED1 respectively, based on the evaporation rate of the Alq3, are produced by doping as well. The current-voltage characteristics of these experiments are shown in FIG. 7. Compared to a pure Alq3 layer, a higher output current as a function of the dopant concentration can be identified, both with a positive and a negative voltage profile based on the ITO electrode. The good effectiveness of the dopant can also be inferred from the symmetric profile of the current density/voltage curve for both dopant concentrations.

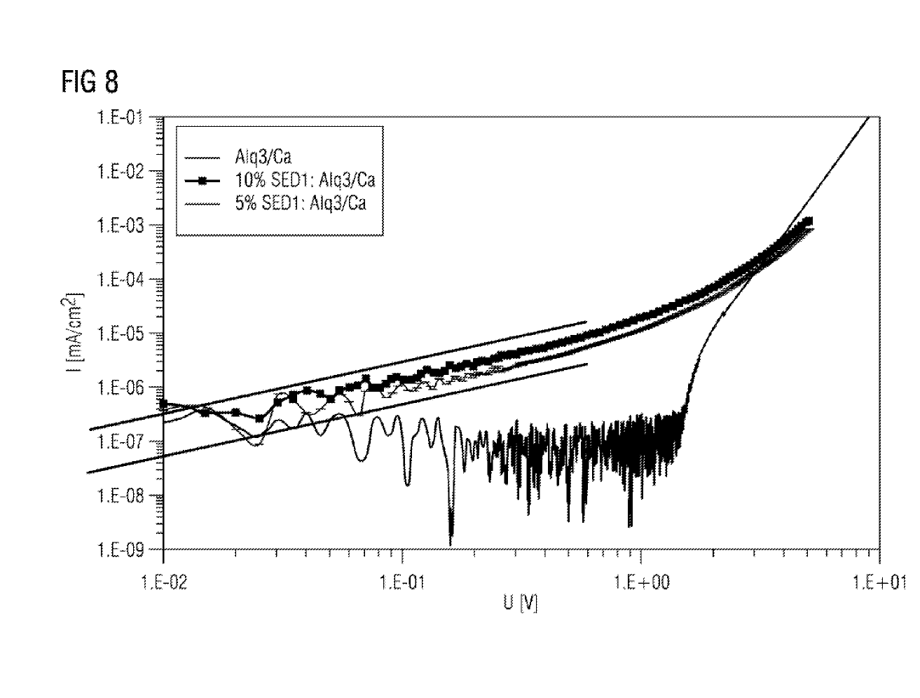

The rise in the current at low voltage values (weak electrical field, see FIG. 8) shows ohmic behavior, which suggests both good doping of the semiconductor and good doping of the cathode/organic phase interface.

Overall, the layer with the 10% doping shows a somewhat better profile than the layer with the 5% dopant content because of the higher current densities achieved.

III.A-2 Current-Voltage Characteristics of Alq3 with SED1 with/without Intermediate SED1 Layer

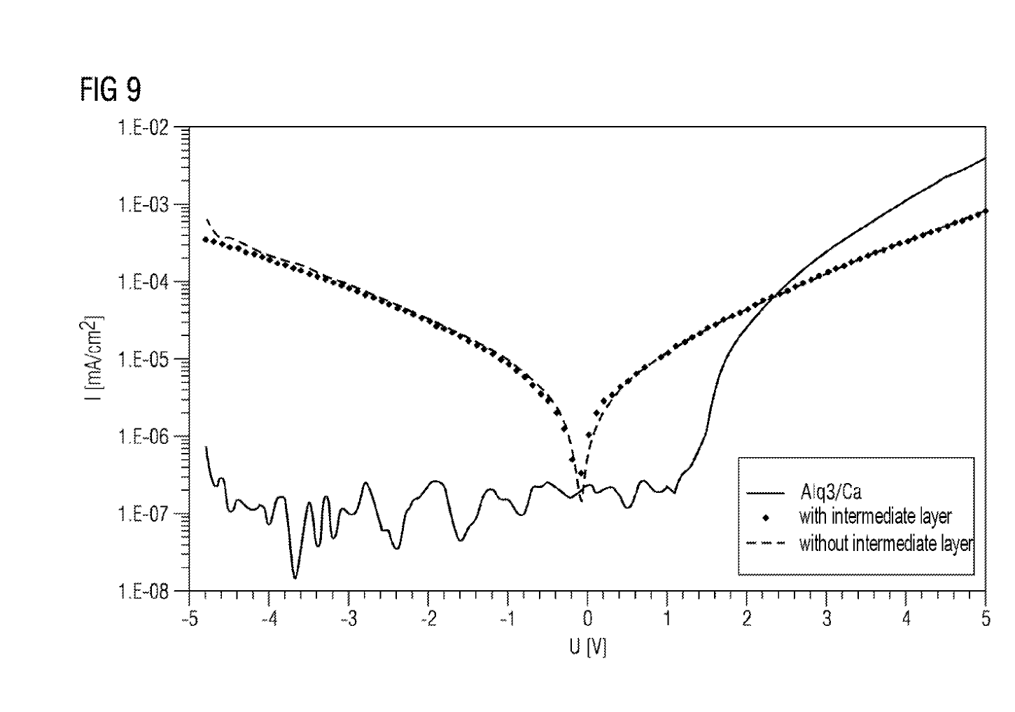

FIG. 9 shows the current/voltage profiles of components having a pure Alq3 layer, an Alq3 layer doped with 5% SED1 and a component having an Alq3 layer doped with 5% SED1 and an additional 15 nm-thick SED1 layer which has been deposited between the calcium cathode and doped electron transport layer. The individual doped layers differ only insignificantly in terms of their current/voltage profiles. This means that the pure SED1 layer is “invisible” and the current is a pure function of the dopant. The curve profile shows that SED1 electrons are injected from the calcium cathode. This is again an indication of good electron-releasing properties of the SED1 within an electronic component and of the good doping properties of the SED1 for electron transport materials in general.

III.A-3 Current-Voltage Characteristics of ETM-036 with SED1

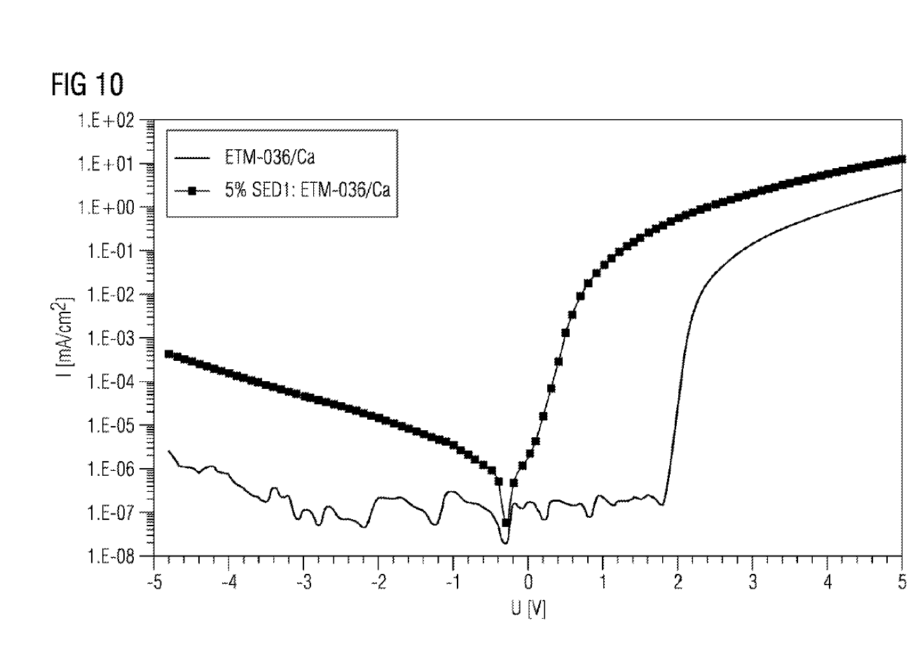

FIG. 10 shows the current/voltage characteristics of a component of size 4 mm² with an ETM-036 layer of thickness 200 nm (ETM-036 is an electron transport material from Merck OLED Materials GmbH or Merck KGaA), with and without SED1 as dopant. Compared to a pure ETM-036 layer, a higher output current is found for the layer doped with 5% SED1, both with a positive and negative voltage profile based on the ITO electrode.

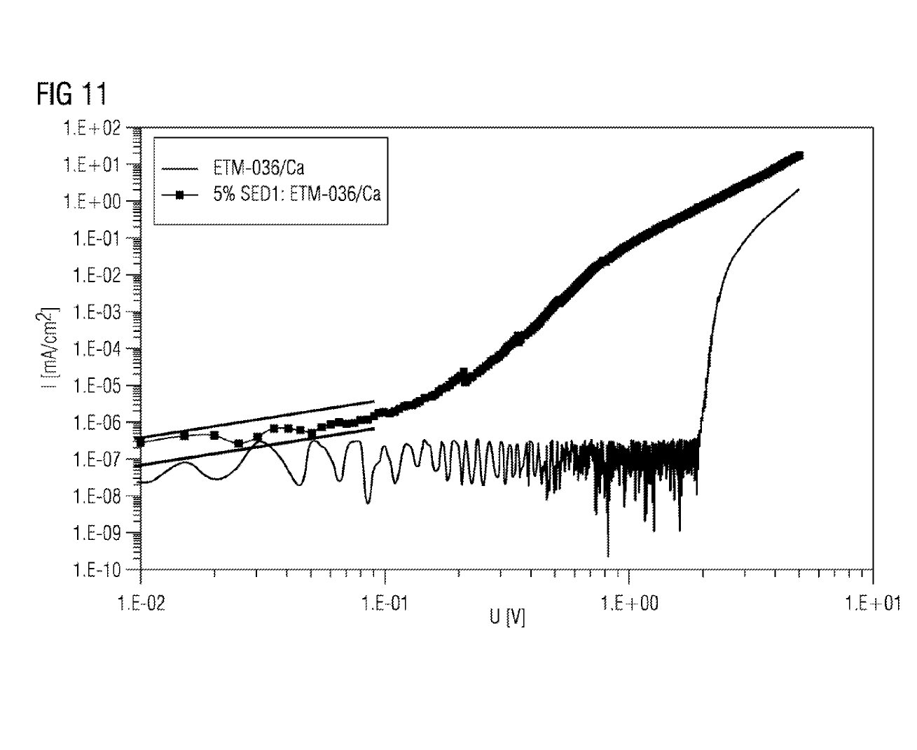

The rise in the current at low voltage values (weak electrical field, see FIG. 11) shows ohmic behavior, which suggests both good doping of the semiconductor and good doping of the cathode/organic phase interface.

III.A-4 Current-Voltage Characteristics of TMM-004 with SED1

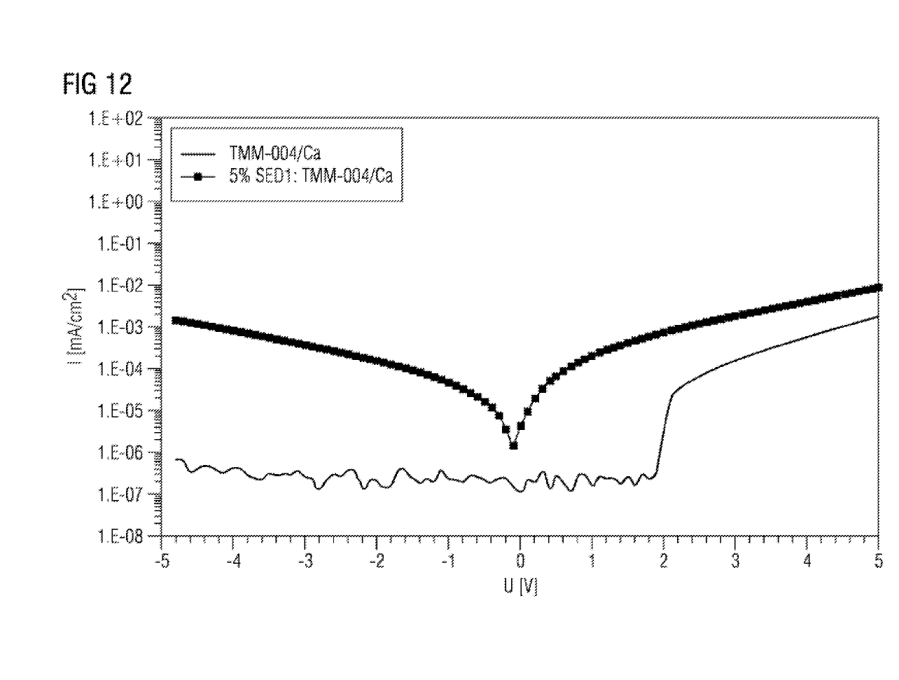

FIG. 12 shows the current/voltage characteristics of a component of size 4 mm² with a TMM-004 layer of thickness 200 nm (TMM-004 is a triplet host and an electron transport material from Merck OLED Materials GmbH or Merck KGaA), with and without SED1 as dopant. Compared to a pure TMM-004 layer, a higher output current is found for the layer doped with 5% SED1, both with a positive and negative voltage profile based on the ITO electrode.

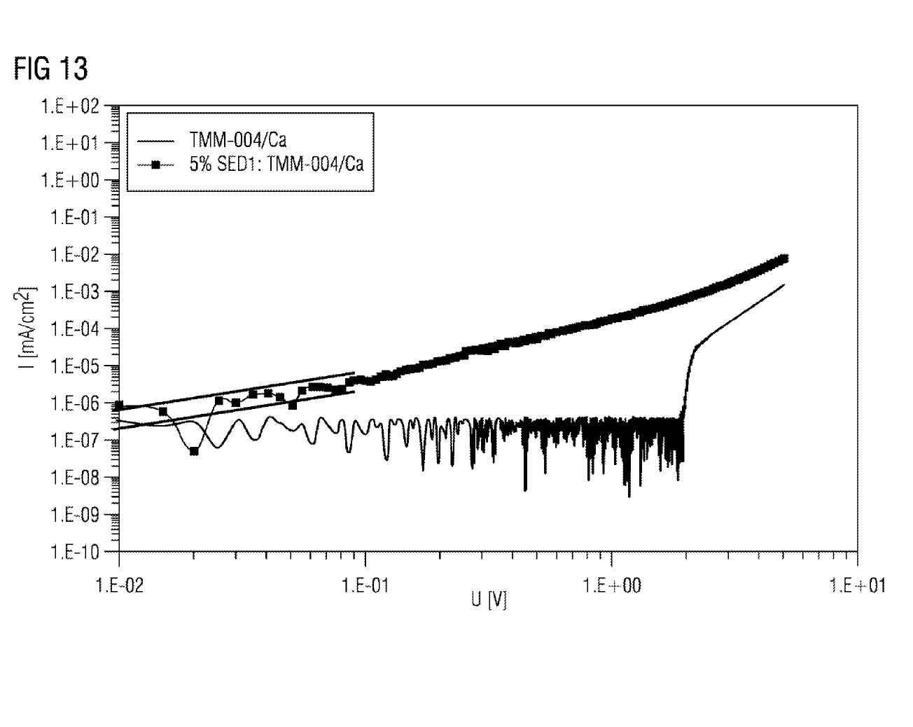

The rise in the current at low voltage values (weak electrical field, see FIG. 13) shows ohmic behavior, which suggests both good doping of the semiconductor and good doping of the cathode/organic phase interface.

### III.B Absorption Spectra of SED1

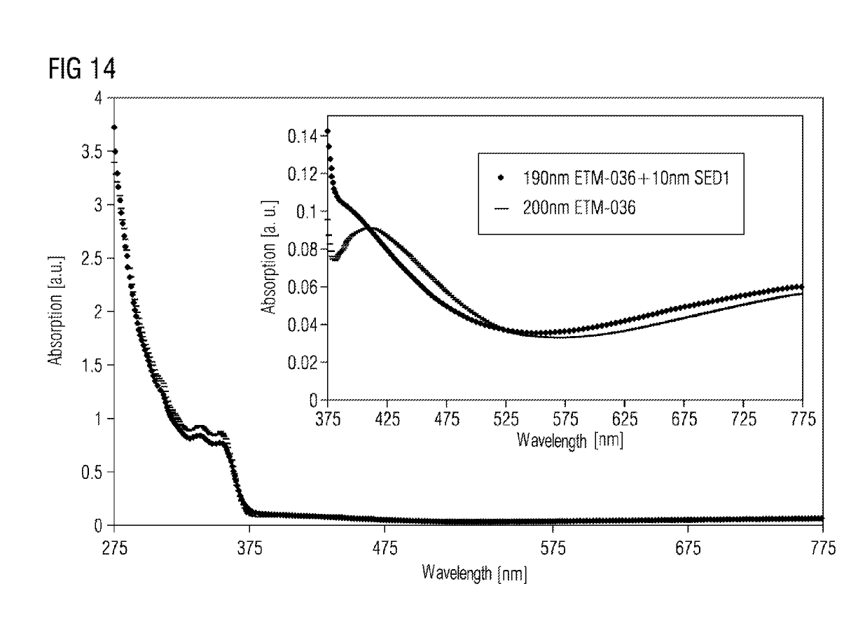

Under the same experimental conditions and with the same layer structure as outlined in example III.A-3, a quartz glass substrate is coated. The setup does not have any electrical contact layers and was chosen merely to determine the optical properties. FIG. 14 shows the absorption properties of an ETM-03 layer and an ETM-03 layer doped with 5% SED1. Both layers show an absorption maxima around 354 nm, with a lower absolute absorption of the doped ETM-03 layer. The decrease in the absorption correlates with the concentration of ETM-03, which suggests that the absorption at these wavelengths is determined principally by the electron transport material.

In a higher wavelength range from about 535 nm, a higher absorption of the SED1-doped layer is found. This may indicate the formation of weak charge transfer complexes between the dopant and the electron transporter. This again is a very strong indication of a doping effect. There is therefore good agreement between the optical and electrical measurements.

The invention has been described in detail with particular reference to preferred embodiments thereof and examples, but it will be understood that variations and modifications can be effected within the spirit and scope of the invention covered by the claims which may include the phrase “at least one of A, B and C” as an alternative expression that means one or more of A, B and C may be used, contrary to the holding in Superguide v. DIRECTV, 69 USPQ2d 1865 (Fed. Cir. 2004).

1-11. (canceled)

12. An organic electronic component comprising:
at least two electrodes; and
an organic electron transport layer containing an organic n-dopant, the organic n-dopant containing at least two cyclic carbene groups that are bonded via a bridge to form an organic electron donor compound, the cyclic carbene groups not being dissociated on electronic excitation of the compound and at least one carbene base structure being aromatized, the carbene groups not being joined directly to one another via a metal ligand.

13. The organic electronic component as claimed in claim 12, wherein the carbene groups of the organic n-dopant are bonded directly to one another by a double bond.

14. The organic electronic component as claimed in claim 12, wherein the bridge of the organic n-dopant contains at least one quinoid ring system.

15. The organic electronic component as claimed in claim 12, wherein at least one of the carbene groups in the organic n-dopant contains a 5- or 6-membered ring having at least one heteroatom.

16. The organic electronic component as claimed in claim 12, wherein each of the carbene groups in the organic n-dopant has a same structure and each of the carbene groups in the organic n-dopant contains at least one 5- or 6-membered ring.

17. The organic electronic component as claimed in claim 12, wherein at least one of the carbene groups in the organic n-dopant contains a tetrazinodihetarene.

18. The organic electronic component as claimed in claim 12, wherein the organic n-dopant contains a bis-pyran.

19. The organic electronic component as claimed in claim 12, wherein the organic n-dopant contains 2,2′,6,6′-tetraphenyl-4,4′-dipyran.

20. The organic electronic component as claimed in claim 12, wherein the organic n-dopant contains N,N,N′,N′-tetramethyl-7,8-dihydro-6H-dipyrido-[1,2-a;2′,1′-c][1,4]diazepine-2,12-diamine (SED1).

21. An organic electronic transport layer comprising:
an organic n-dopant, the organic n-dopant containing at least two cyclic carbene groups that are bonded via a bridge to form an organic electron donor compound, the cyclic carbene groups not dissociating on electronic excitation of the compound and at least one carbene base structure being aromatized, the carbene groups not being joined directly to one another via a metal ligand.

22. An organic electron transport layer n-dopant comprising:
at least two cyclic carbene groups that are bonded via a bridge to form an organic electron donor compound, the cyclic carbene groups not dissociating on electronic excitation of the compound and at least one carbene base structure being aromatized, the carbene groups not being joined directly to one another via a metal ligand.

23. The organic electronic component as claimed in claim 12, wherein each of the carbene groups are hydrocarbons that are partially unsaturated.

24. The organic electronic component as claimed in claim 12, wherein, under electronic excitation, the organic electron donor compound releases an electron to an acceptor while retaining its bonding structure.

25. The organic electronic transport layer as claimed in claim 21, wherein the carbene groups of the organic n-dopant are bonded directly to one another by a double bond.

26. The organic electronic transport layer as claimed in claim 21, wherein the bridge of the organic n-dopant contains at least one quinoid ring system.

27. The organic electronic transport layer as claimed in claim 21, wherein at least one of the carbene groups in the organic n-dopant contains a 5- or 6-membered ring having at least one heteroatom.

28. The organic electron transport layer n-dopant as claimed in claim 22, wherein the carbene groups of the organic n-dopant are bonded directly to one another by a double bond.

29. The organic electron transport layer n-dopant as claimed in claim 22, wherein the bridge of the organic n-dopant contains at least one quinoid ring system.

30. The organic electron transport layer n-dopant as claimed in claim 22, wherein at least one of the carbene groups in the organic n-dopant contains a 5- or 6-membered ring having at least one heteroatom.
